(19) United States
(12) Patent Application Publication
(10) Pub. No.: US 2024/0388023 A1
(43) Pub. Date: Nov. 21, 2024

(54) MIDBOARD CONNECTOR WITH GROUND CONTACTS FOR HIGH FREQUENCY OPERATION

(71) Applicant: Amphenol Corporation, Wallingford, CT (US)

(72) Inventors: Ali Hammoodi, Nashua, NH (US); Arkady Y. Zerebilov, Lancaster, PA (US); C. Christopher Michlik, Toronto (CA); Michael Rowlands, Milford, MA (US); Jason Si, Toronto (CA)

(73) Assignee: Amphenol Corporation, Wallingford, CT (US)

(21) Appl. No.: 18/654,326

(22) Filed: May 3, 2024

Related U.S. Application Data
(60) Provisional application No. 63/502,410, filed on May 15, 2023.

(51) Int. Cl. H01R 12/71; H01R 12/72; H01R 13/6471; H01R 13/6587

(52) U.S. Cl. CPC H01R 12/716; H01R 12/724; H01R 13/6471; H01R 13/6587

(57) ABSTRACT

A high frequency, high density electrical connector with structures that shorten ground loops in regions of the connector in which shorter ground loops results in less crosstalk and/or less insertion loss at high frequencies. The connector may multiple conductive elements including one or more signal conductors in line with ground conductors. The structures may be near the distal ends of the ground conductors and may divide larger ground loops into smaller ground loops in regions of the connector where the ground conductors are separated from a ground conductor in the complementary mating structure by a small distance. These structures may include a ground strip attached to extensions from a shield within the connector and/or a secondary beam extending from the ground conductors and positioned to contact the ground conductors in the complementary mating structure.

### RELATED APPLICATION

This application claims the benefit under 35 U.S.C. § 119 (e) of U.S. Provisional Application Ser. No. 63/502,410, filed on May 15, 2023, under Attorney Docket No. A0863.70165US00 and entitled “MIDBOARD CONNECTOR WITH GROUND CONTACTS FOR HIGH FREQUENCY OPERATION,” which is hereby incorporated herein by reference in its entirety.

### TECHNICAL FIELD

Disclosed embodiments are related to midboard connectors with high frequency performance, including pressure mount midboard connectors.

### BACKGROUND

Electrical connectors are used in many electronic systems. It is generally easier and more cost effective to manufacture a system as separate components, which may be joined with electrical connectors. Having separable connectors enables components of the electronic system from different manufacturers to be readily assembled. Separable connectors also enable components to be readily replaced after the system is assembled, either to replace defective components or to upgrade the system with higher performance components.

An electronic system, for example, may be assembled from multiple printed circuit boards that are joined through separable connectors. For example, one printed circuit board may serve as a backplane and other printed circuit boards, called “daughterboards,” “daughtercards,” may be connected through the backplane. Connectors mounted on daughtercards may be plugged into the connectors mounted on the backplane. In this way, signals may be routed among the daughtercards through the backplane. The daughtercards may plug into the backplane at a right angle. The connectors used for these applications may therefore include a right angle bend and are often called “right angle connectors.”

Connectors may also be used in other configurations for interconnecting printed circuit boards. For example, one or more smaller printed circuit boards may be connected to another larger printed circuit board. In such a configuration, the larger printed circuit board may be called a “motherboard” and the printed circuit boards connected to it may be called daughterboards or “add in cards”. Depending on the nature of the electronic system, the printed circuit boards may have various orientations, which impacts the types of connectors used to form interconnections between the boards. Boards aligned in parallel may be connected through “stacking connectors” or “mezzanine connectors.” Boards positioned with edges orthogonal and facing each other may be connected through orthogonal connectors.

In some portions of an electronic system, signals may be routed through cables. Routing signals through a cable, rather than through a printed circuit board, may be advantageous because the cables provide signal paths with high signal integrity, particularly for high frequency signals, such as those above 40 Gbps using an NRZ protocol or greater than 50 Gbps using a PAM4 protocol. Known cables have one or more signal conductors, which are surrounded by a dielectric material, which in turn is surrounded by a conductive layer. The conductive layer is usually formed using foil, such as aluminized Mylar. A protective jacket, often made of plastic, may surround these components. Additionally, the jacket or other portions of the cable may include fibers or other structures for mechanical support.

At an end of the cable, where the cable is to be terminated to a connector or other terminating structure, the protective jacket, the foil, and the dielectric may be removed, leaving portions of the signal conductors exposed at the end of the cable. In another segment near the end of the cable, the protective jacket may be removed, exposing the conductive layer. The signal conductors may be attached to conductive elements serving as mating contacts in the connector. The conductive layer may be attached to a ground conductor in the connector. In this way, any ground return path may be continued from the cable to the terminating structure.

To connect one electronic device to another component via a cable, the device may have an “I/O connector.” The I/O connector may be mounted to a printed circuit board inside the electronic device, usually at an edge of the printed circuit board. That connector may be configured to receive a plug at one end of a cable, such that the cable is connected to the printed circuit board through the I/O connector. The other end of the cable may be connected to another electronic device or other component of an electronic system.

Cables have also been used to make connections within the same electronic device. The cables may be used to route signals from an I/O connector to a processor assembly at the interior of printed circuit board, away from the edge at which the I/O connector is mounted. In other configurations, both ends of a cable may be connected to the same printed circuit board. The cables can be used to carry signals between components mounted to the printed circuit board near where each end of the cable connects to the printed circuit board.

High speed cables and connectors have been used, for example, inside electronic devices to route signals to or from processors and other electrical components that process a large number of high speed, high bandwidth signals. Such components may be mounted at the midboard region of a printed circuit board. The cables may be terminated with a connector that mates to the printed circuit board near these components. These cables attenuate signals passing to or from these components less than what might occur were the same signals routed through the printed circuit board.

Regardless of their use, connectors have conductive elements that carry signals through the connector. Each conductive element has a mating contact portion that makes connection to a complementary mating contact portion in a complementary mating component. The complementary mating component may be another connector or may be a printed circuit board. In a system in which the connector mates to a printed circuit board, the surface of the printed circuit board may have conductive pads that serve as mating contact portions. Connections may be formed by pressing the connector against the surface of the printed circuit board such that mating contact portions of the conductive elements in the connector press against the conductive pads on the printed circuit boards. Connectors in which connections are made by pressing the connector against a printed circuit board are called pressure mount connectors.

### SUMMARY

Some embodiments relate to a connector configured to mate with a complementary mating structure having a first surface, comprising: a housing; a plurality of signal conductive elements held by the housing; and a plurality of ground conductive elements held by the housing, each ground conductive element comprising: a first beam forming a first mating contact portion, the first beam extending in a first direction; and a second beam forming a second mating contact portion, the second beam extending in a second direction, wherein the second direction is transverse to the first direction such that the first and second contact portions are both adapted to contact a conductive pad formed on the first surface when the connector mates with the complementary mating structure.

In some embodiments, the first direction is opposite the second direction when projected on a plane defined by the first surface.

In some embodiments, the first beam, the second beam and the conductive pad are in a ground loop when the connector mates with the complementary mating structure.

In some embodiments, the first beam and the second beam are configured such that a conducting path through the first beam, the second beam and the conductive pad between the first beam and the second beam is between 2 mm and 3 mm when the connector mates with the complementary mating structure.

In some embodiments, the first and second contact portions are spaced apart from each other, when the connector is mated with the complementary mating structure, by a distance that is between 0.8 mm and 1.4 mm.

In some embodiments, the connector further comprises a ground member from which first and second ground conductive elements of the plurality of ground conductive elements extend, wherein first and second signal conductive elements of the plurality of signal conductive elements are disposed between the first ground conductive element and the second conductive element.

In some embodiments, the second beam has a length between 0.4 mm and 0.8 mm.

In some embodiments, the first mating contact portion has a first contact surface; a base of the second beam is joined to the first beam; and a distance between the first contact surface and the base of the second beam is between 0.6 mm and 1.0 mm.

In some embodiments, the first beam and the second beam extend in directions separated by an angle between 100 and 125 degrees, when the first beam and the second beams are in an uncompressed state.

In some embodiments, the connector is configured such that, when the connector is mated to the complementary mating structure, the second beam is joined to the first beam at a point that is 0.2 to 0.6 mm from the first surface.

In some embodiments, the plurality of ground conductive elements are configured so that pressing the connector towards the first surface of the complementary connector, as the connector is mating with the complementary connector, causes the first and second contact portions to slide away from each other on the conductive pad.

In some embodiments, the connector further comprises a ground strip positioned such that pressing the connector towards the first surface of the complementary mating structure, when the connector is mated with the complementary mating structure, causes at least one ground conductive element to electrically couple to the ground strip.

In some embodiments, pressing the connector towards the plane of the first surface of the complementary connector, when the connector is mated with the complementary connector, causes at least two of the plurality of ground conductive elements to electrically coupled to the ground strip.

In some embodiments, the connector further comprises a ground shield welded to the at least two of the plurality of ground conductive elements; the ground shield has a plurality of extensions extending therefrom; and the ground strip is attached to the plurality of extensions.

In some embodiments, the connector further comprises a plurality of cables, each cable being connected to a respective pair of the plurality of signal conductive elements.

In some embodiments, the connector exhibits, at a frequency of 35 GHZ, a far end crosstalk that is between −40 dB and −50 dB.

In some embodiments, the plurality of signal conductive elements and the plurality of ground conductive elements are arranged in a plurality of columns.

In some embodiments, the first beam is adapted to exert a first force normal to a plane defined by the first surface of the complementary mating structure when the connector is mated with the complementary mating structure, and the second beam is adapted to exert a second force normal to the plane defined by the first surface of the complementary connector when the connector is mated with the complementary mating structure, the first force being greater than the second force.

In some embodiments, each signal conductive element comprises a third beam forming a third mating contact portion, wherein the first contact portions and the third contact portions form a column.

In some embodiments, the first beam further comprises an enclosed opening, and the second beam joins a region of the ground conductive element that is adjacent the enclosed opening.

Some embodiments relate to a connector configured to mate with a complementary mating structure having a first surface, comprising: a housing; a plurality of signal conductive elements held by the housing; and a plurality of ground conductive elements held by the housing, each ground conductive element comprising a first beam comprising a first mating contact surface and a second beam forming a second mating contact surface, wherein the first and second contact portions are both configured to contact a conductive pad on the first surface when the connector mates with the complementary mating structure, wherein the plurality of ground conductive elements are configured so that pressing the connector towards the first surface, when the connector is mated with the complementary mating structure, causes the first and second contact portions to slide away from each other on the conductive pad.

In some embodiments, the first beam, the second beam and the conductive pad are in a ground loop when the connector mates with the complementary mating structure.

In some embodiments, the first beam and the second beam are configured such that a conducting path through the first beam, the second beam and the conductive pad between the first beam and the second beam is between 2 mm and 3 mm when the connector mates with the complementary mating structure.

In some embodiments, the first and second contact portions are spaced apart from each other, when the connector is mated with the complementary mating structure, by a distance that is between 0.8 mm and 1.4 mm.

In some embodiments, the first and second contact portions are spaced apart from each other, when the connector is mated with the complementary mating structure, by a distance that is between 0.8 mm and 1.4 mm.

Some embodiments relate to a method for mating a connector with a complementary mating structure having a first surface, the connector comprising a plurality of signal conductive elements and a plurality of ground conductive elements, each ground conductive element comprising first and second beams, the method comprising: placing the plurality of signal conductive elements in contact with a first plurality of conductive pads formed on the first surface of the complementary connector; and placing the plurality of ground conductive elements in contact with one or more conductive pads on the first surface of the complementary mating structure at least in part by: placing the first beams in contact with pads of the one or more conductive pads; placing the second beams in contact with pads of the one or more conductive pads; and causing the first beams and the second beams to slide away from each other on the pads of the one or more conductive pads.

In some embodiments, placing the plurality of ground conductive elements in contact with pads of the one or more conductive pads further comprises forming a plurality of ground loops, each ground loop traversing at least portions of two first beams, two second beams and a ground structure within the complementary mating structure.

In some embodiments, placing the plurality of ground conductive elements in contact with the one or more conductive pads further comprises: exerting a first force normal to the first surface of the complementary mating structure with the first beam; and exerting a second force normal to the first surface of the complementary mating structure with the second beam, wherein the first force is greater than the second force.

In some embodiments, the first beams and the plurality of signal conductive elements form a column.

### BRIEF DESCRIPTION OF DRAWINGS

Examples of the concepts described herein are illustrated in the accompanying drawings. In the drawings, each identical or nearly identical component that is illustrated in various figures may be represented by a like numeral. For purposes of clarity, not every component may be labeled in every drawing. In the drawings:

FIG. 1 is a perspective view of a portion of an electronic system with a mid-board connector;

FIG. 2 is a perspective view of an exemplary mid-board connector and an exemplary mechanical structure for urging the connector against a substrate;

FIG. 3 is a bottom perspective view of the exemplary mid-board connector of FIG. 2;

FIG. 4 is an exploded view of an exemplary terminal assembly that may be integrated into the mid-board connector of FIG. 2;

FIG. 5A is a front perspective of an exemplary high frequency terminal assembly that may be integrated into the mid-board connector of FIG. 2;

FIG. 5B is a rear perspective view of the exemplary high-frequency terminal assembly of FIG. 5A;

FIG. 5C is a side view of the mating and of the exemplary terminal assembly of FIG. 5A;

FIG. 6A is a perspective view of conductive elements of the exemplary terminal assembly of FIG. 5A mated to a complementary mating structure;

FIG. 6B is an enlarged view of the mating portion of a ground conductor of the exemplary terminal assembly of FIG. 5A;

FIG. 7 is a side view of the mating portion of a ground conductor of the exemplary terminal assembly of FIG. 5A, shown mated to an alternative complementary mating structure;

FIG. 8 is a plot of insertion loss for a simulated connector with ground conductors with and without secondary beams;

FIG. 9 is a plot of far end crosstalk for a simulated connector with ground conductors with and without secondary beams;

FIG. 10 is a plot of insertion loss for a simulated connector with ground conductors and with and without a ground strip bridging the ground conductors when engaged with the complementary mating structure;

FIG. 11 is a plot of far end crosstalk for a simulated connector with ground conductors and with and without a ground strip bridging the ground conductors when engaged with a complementary mating structure.

The foregoing is a non-limiting summary of the invention, which is defined by the appended claims.

### DETAILED DESCRIPTION

The inventors have recognized and appreciated connector designs that enable electronic devices to operate at high data rates. With these techniques, signal integrity through interconnections including those connectors may be improved, such as via a reduction of insertion loss and/or crosstalk. These improvements may be pronounced for high frequency signals necessary for high data rate operation. Accordingly, techniques as described herein may be used in a connector to enable operation at high data rates, such as data rates that operate based on signals with frequencies above 25 GHz or that provide data rates of greater than 100 Gbps using a PAM4 protocol.

Techniques as described herein may include contact portions of conductive elements serving as ground conductors that alter electrical properties near the mating contact portions. In some examples, the mating contact portion of a ground conductor may have a primary beam and a secondary beam. The secondary beam may extend in a direction transverse to the primary beam. Both the primary beam and secondary beam may contact a mating contact portion of a complementary component, with the secondary beam extending relative to the primary beam in a direction that separates the locations at which the primary beam and the secondary beam contact the complementary component. Such a structure may be simply manufactured by stamping the secondary beam as part of the primary beam and bending the secondary beam relative to the primary beam.

In a connector in which signal conductors and ground conductors are interspersed, ground conductors bounding groups of one or more signal conductors may each have a primary and secondary beam. Performance benefits may be seen even in a dense connector, such as a connector in which mating contact portions of conductive elements in a row are spaced on center between 0.3 mm and 0.6 mm, or between 0.35 and 0.45 mm, in some examples.

A ground contact structure as described herein may improve performance in a connector that is pressed against a surface of a mating component for making connections. The primary and secondary beams, for example, may press against one or more conductive pads on a surface of the mating component. The primary beam may be at an acute angle with respect to that surface. For example, the angle may be in the range of 20 to 40 degrees or between 25 and 35 degrees. Such contact structures may be beneficial in a connector in which the secondary beam joins the primary beam at a location that is separated from the plane of the surface, in a direction perpendicular to that plane, by a distance in the range of 0.2 mm to 0.6 mm, such as 0.4 mm.

The inventors theorize that, in such a connector, ground loops through the contact structure are separated from ground pads on the surface of the mating component by a distance that is prone to ground resonances at frequencies in the operating frequency range of a connector carrying high data rates, which degrades signal integrity at high data rates. By changing through incorporation of a secondary beam, the paths through the ground structures of the connector and/or mating component are altered in a way that results in a reduced impact within the operating frequency range of the connector.

An improvement may similarly be achieved by including a ground strip above the contact portions of ground conductors such that the ground conductors are connected through the ground strip when deflected during mating of the connector to a complementary mating structure, such as a printed circuit board, which may be a motherboard or a paddle card of a plug connector, for example. The ground strip may extend from an extension of a shield internal to the connector, which may enable positioning of the ground strip near the ends of the ground conductors, where attaching a ground conductor in other ways might otherwise be difficult. Such a ground strip may be used instead of or in addition to secondary beams for the ground conductors.

Turning to the figures, specific non-limiting embodiments are described in further detail. It should be understood that the various systems, components, features, and methods described relative to these embodiments may be used either individually and/or in any desired combination as the disclosure is not limited to only the specific embodiments described herein.

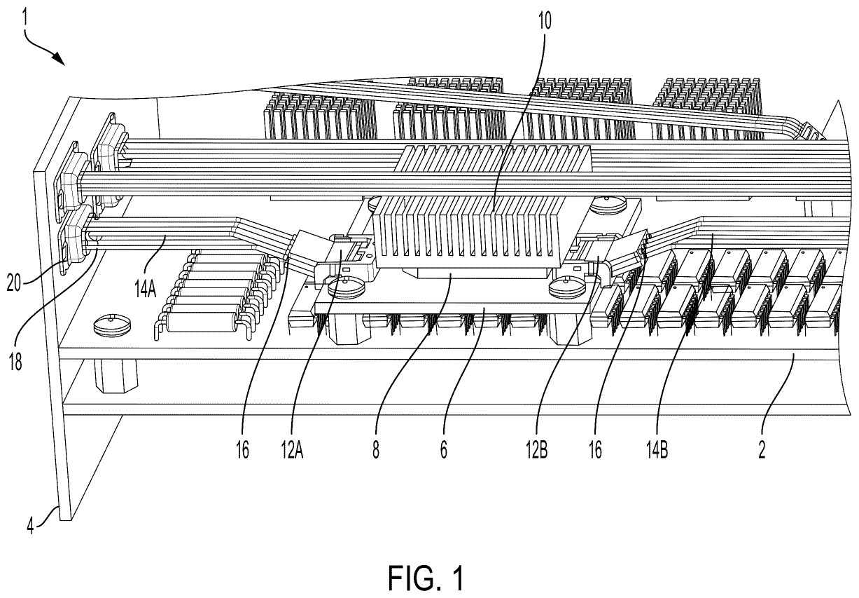

FIG. 1 is a perspective view, respectively of an illustrative electronic system 1 in which a cabled connection is made between a connector mounted at the edge of a printed circuit board 2 near a panel 4. In this example, printed circuit board 2 is a motherboard, and a midboard connector 12A mated to a printed circuit board, which here is a daughterboard 6, mounted in a midboard region above printed circuit board 2. In the illustrated example, the midboard connector 12A is used to provide a low loss path for routing electrical signals between one or more components, such as component 8, mounted to printed circuit daughterboard 6 and a location off the printed circuit board. Component 8, for example, may be a processor or other integrated circuit chip. However, any suitable component or components on daughterboard 6 may receive or generate the signals that pass through the midboard connector 12A.

In the illustrated example, the midboard connector 12A couples signals to and from component 8 through an I/O connector 20 mounted in panel 4 of an enclosure. The I/O connector may mate with a transceiver terminating an active optical cable assembly that routes signal to or from another device. Panel 4 is shown to be orthogonal to circuit board 2 and daughterboard 6. Such a configuration may occur in many types of electronic equipment, as high speed signals frequently pass through a panel of an enclosure containing a printed circuit board and must be coupled to high speed components, such as processors or ASICS, that are further from the panel than high speed signals can propagate through the printed circuit board with acceptable attenuation.

In the example of FIG. 1, connector 12A mounted at the edge of daughterboard 6 is configured to support connections to an I/O connector 20. As can be seen, cabled connections may connect multiple locations within an electronic system. For example, a second connector 12B makes connections to daughterboard 6 from another location (not shown).

Cables 14A and 14B may electrically connect midboard connector assemblies 12A and 12B to locations remote from component 8 or otherwise remote from the location at which midboard connector assemblies 12A or 12B are attached to daughterboard 6. In the illustrated embodiment of FIG. 1, first ends 16 of the cables 14A and 14B are connected to the midboard connector 12A or 12B. Second ends 18 of the cables 14A are connected to an I/O connector 20. Connector 20 may have any suitable function and/or configuration, as the present disclosure is not so limited. In some embodiments, higher frequency signals, such as signals having components above 10 GHz, such as up to 20 GHz, 25 GHz, 30 GHZ, 35 GHZ or 40 GHz, for example, may be connected through cables 14A and 14B, which might be susceptible to unacceptably large signal losses if coupled through a printed circuit board for distances greater than approximately six inches.

Cables 14A may have a length that enables midboard connector 12A to be spaced from second ends 18 at connector 20 by a first distance. In some embodiments, the first distance may be longer than a second distance over which signals at the frequencies passed through cables 14A could propagate along traces within PCB 2 and daughterboard 6 with acceptable losses. In some embodiments, the first distance may be at least 6 inches, in the range of 1 to 20 inches, or any value within the range, such as between 6 and 20 inches. However, the upper limit of the range may depend on the size of PCB 2.

Cables 14B may have first ends 16 attached to midboard connector 12B and second ends attached to another location, which may be a connector like connector 20 or other suitable location.

Taking midboard connector 12A as representative, the midboard connector may be mated to printed circuit board, such as daughter card 6, near components, such as component 8, which receive or generate signals that pass through cables 14A. As a specific example, midboard connector 12A may be mounted within six inches of component 8, and in some embodiments, within four inches of component 8 or within two inches of component 8. Midboard connector 12A may be mounted at any suitable location at the midboard, which may be regarded as the interior regions of daughterboard 6, set back from the edges of daughterboard 6 so as to occupy less than 100% of the area of the daughterboard 6. Such an arrangement may provide a low loss path through cables 14. In the electronic device illustrated in FIG. 1, the distance between connector 12A and processor 8 may be of the order of 1 inch or less.

In some embodiments, midboard connector 12A may be configured for mating to a daughterboard 6 or other PCB in a manner that allows for case of routing of signals coupled through the connector. For example, an array of signal pads to which terminals of midboard connector 12A are mated may be spaced from the edge of daughterboard 6 or another PCB such that traces may be routed out of that portion of the footprint in all directions, such as towards component 8.

In the example of FIG. 1, connector 12A includes cables 14A aligned in multiple rows at first ends 16. In the depicted embodiment, cables are arranged in an array at first ends 16 attached to midboard connector 12A. Such a configuration may result in relatively short breakout regions that maintain signal integrity in connecting to an adjacent component in comparison to routing patterns that might be required were those same signals routed out of an array with more rows and fewer columns.

While FIG. 1 depicts a connector connecting to a daughter card at a midboard location, it should be noted that connector assemblies described herein may be used to make connections to other substrates and/or other locations within an electronic device.

As discussed herein, midboard connector assemblies may be used to make connections to processors or other electronic components. Those components may be mounted to a printed circuit board or other substrate to which the midboard connector might be attached. Those components may be implemented as integrated circuits, with for example one or more processors in an integrated circuit package, including commercially available integrated circuits known in the art by names such as CPU chips, GPU chips, microprocessor, microcontroller, or co-processor. Alternatively, a processor may be implemented in custom circuitry, such as an ASIC, or semicustom circuitry resulting from configuring a programmable logic device. As yet a further alternative, a processor may be a portion of a larger circuit or semiconductor device, whether commercially available, semi-custom or custom. As a specific example, some commercially available microprocessors have multiple cores in one package such that one or a subset of those cores may constitute a processor. Though, a processor may be implemented using circuitry in any suitable format.

In the illustrated embodiment, the processor is illustrated as a packaged component separately attached to daughtercard 6, such as through a surface mount soldering operation. In such a scenario, daughtercard 6 serves as a substrate to which midboard connector 12A is mated.

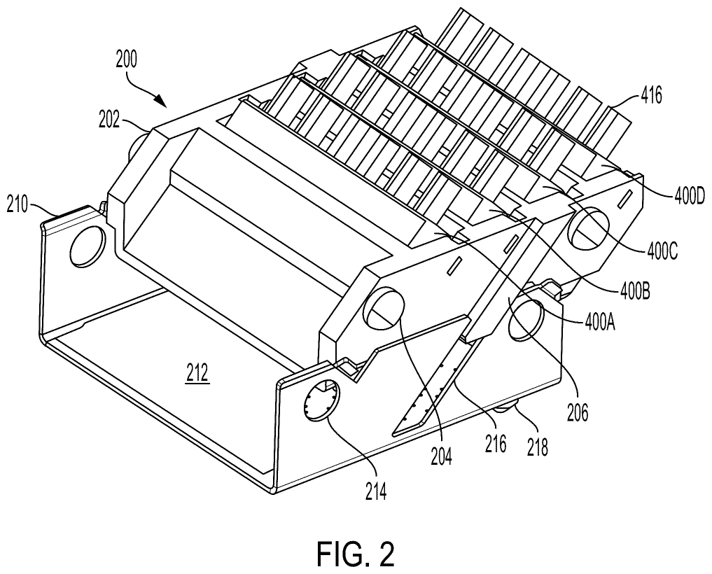

FIG. 2 illustrates a connector 200 that may terminate cables 416 and make a connection to a substrate, such as a printed circuit board. In FIG. 2, only portions of the cables 416 near connector 200 are shown for simplicity. In an electronic system incorporating connector 200, the cables may be longer than illustrated and may be connected to other portions of the system, such as another connector or remote location on a printed circuit board. Connector 200, for example, may be used in an electronic system 1, as shown in FIG. 1, in place of midboard connector 12A.

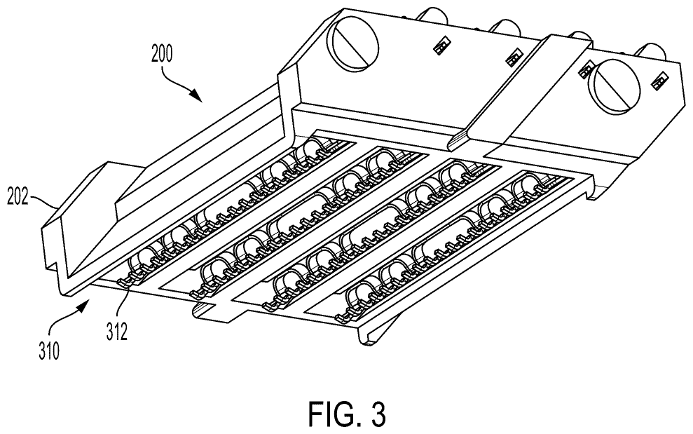

In this example, connector 200 has a housing 202 that holds conductive elements terminating multiple cables 416. The conductive elements may have mating contact portions 312 exposed at a mounting face 310 (FIG. 3) of housing 202.

Connector 200 is an example of a pressure mount connector. As housing 202 is pressed against the substrate, with mounting face 310 facing the substrate, the mating contact portions 312 may press against conductive structures on the surface of the substrate, making connections.

A pressure mount connector may be used with one or more components that secure the connector to the substrate and generate force urging the connector towards the substrate. In the example of FIG. 1, connector 200 is used with a frame 210. Frame 210 may have one or more attachment features that engage the substrate. In this example, frame 210 has one or more posts 218 that may be secured in holes in the substrate, such as via soldering, adhesive, or interference. Alternatively or additionally, frame 210 may have attachment features in other configurations, such as press fits or frame 210 may be attached to the substrate through surface mount soldering, for example.

In this example, frame 210 has an opening 212 in surface intended to be mounted against the substrate. Opening 212 may be sized and positioned such that, when connector 200 is inserted into frame 210, the mounting face 310 of connector 200 is exposed through opening 212 such that it may press against the substrate.

Connector 200 and frame 210 may have one or more complementary engagement features such that when connector 200 is inserted into frame 210, connector 200 is held against the substrate to which frame 210 is attached with sufficient force for the mating contact portions of the conductive elements within connector 200 to make electrical connections to the substrate. In the example of FIG. 2, connector 200 has posts 204 that engage openings 214 in frame 210.

Alternatively or additionally, connector 200 and frame 210 may have one or more complimentary alignment features such that when connector 200 is inserted into frame 210, connector 200 is guided into a position in which mating contact portions of the conductive elements in connector 200 mate with conductive structures on the surface of the substrate. In the example of FIG. 2, frame 210 includes slits 216 that are configured to receive ribs 206 extending from connector 200.

In this example, frame 210 is made from a sheet of metal and may be an integral member. That sheet of metal may be stamped from a sheet of metal and then bent into the desired shape, including features as described above and as illustrated in FIG. 2. If frame 210 is made of conductive material, such as a metal sheet, it optionally may be connected to ground structures on the substrate.

Connector 200 may be assembled from terminal assemblies held in a housing 202. Housing 202 may be insulative. If insulative, housing 202 may be molded, such as from plastic or nylon. Housing 202 may alternatively be conductive or may be electrically lossy. If conductive, housing 202 may be formed of metal, such as by die casting. If lossy, housing 202 may be formed from plastic or nylon filled with conductive particles, for example. If housing 202 is conductive or lossy, it may contact or couple to portions of the lead assemblies that are grounded.

In the illustrated example, each of the lead assemblies, of which lead assemblies 400A . . . 400D are shown, has a column of conductive elements. Some of the conductive elements are configured as signal conductors and others are configured as ground conductors. The conductive elements may be organized in groups, with a group of conductive elements corresponding to a cable 416. For a twinax cable, the cable may be terminated by a group of conductive elements with two signal conductors and two ground conductors. The ground conductors may be on opposing sides of the signal conductors. The ground conductors and the signal conductors may be shaped similarly. In other examples, the signal conductors may be of a first type and the ground conductors may be of a second type, differing from the signal conductors based on width, thickness, proximity to other conductive elements, or other characteristic.

FIG. 3 is a bottom view of connector 200, revealing mating face 310. Mating contact portions 312 of conductive elements within the connector extend through the mating face 310 when in an undeflected state (e.g. while connector 200 is separated from a substrate). In this example, the mating contact portions 312 are arranged in parallel columns. Each column corresponds to a lead assembly, as each lead assembly holds a column of conductive elements in this example.

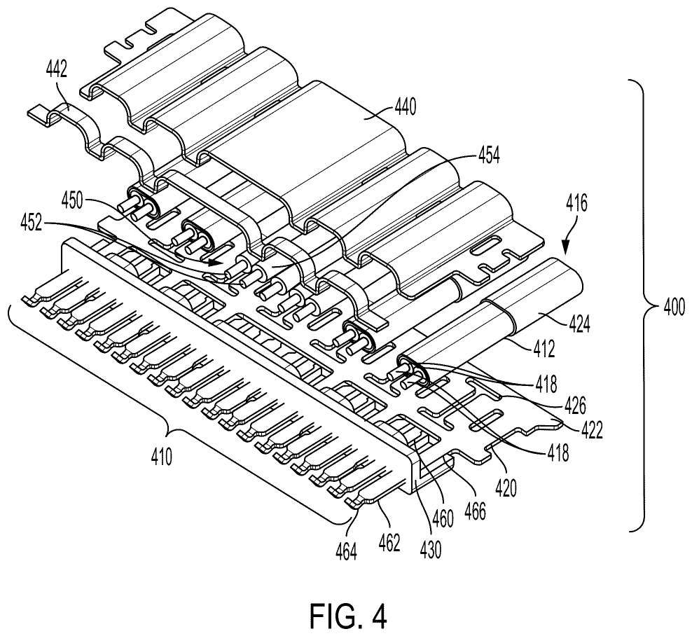

FIG. 4 is an exploded perspective view of an exemplary embodiment of a cable connector terminal assembly 400. Terminal assembly 400 may be any of the terminal assemblies 400A . . . 400D. In some examples, all of the terminal assemblies in a connector may have the same configuration. In other examples, all of the terminal assemblies may be constructed with the same techniques, but adjacent terminal assemblies may have different patterns of signal and ground conductors such that signal conductors in one column are offset, in a direction parallel to the column direction, from signal conductors in an adjacent column. Such a configuration may reduce coupling between the signal conductors, which may reduce crosstalk.

As shown in FIG. 4, the terminal assembly includes a plurality of conductive elements 410 and a cable clamp plate 420. The plurality of terminals and cable clamp plate may be stamped from the same piece of metal, such that the plurality of terminals and cable clamp plate were at one point integral.

As shown in FIG. 4, the terminal assembly also includes a dielectric 430 overmolded over the plurality of conductive elements 410 and a portion of the cable clamp plate 420. The dielectric may be plastic and may physically support the plurality of conductive elements. Accordingly, at least a portion of the plurality of conductive elements may be physically separated from the cable clamp plate (e.g., tie bars are removed) to electrically isolate the conductive elements. The dielectric may maintain the relative position of the conductive elements 410. In the embodiment of FIG. 4, the cable clamp plate 420 also includes retaining tabs 422 configured to be received in corresponding tab receptacles of a cable connector housing. Such an arrangement allows the terminal assembly to be reliably and accurately secured in a cable connector housing.

Each of the conductive element may have a mating contact portion 462. In the example of FIG. 4, all of the conductive elements in a terminal assembly 400 have a similarly shaped mating contact portion extending out of dielectric overmold 430 in a first direction towards a mating interface. In this example the mating contact portions are each shaped as a beam, with a contact surface 464 near a distal end. In this example, the contact surfaces 464 are on a convex portions of respective mating contact portions and may be plated with gold or other material providing for a low contact resistance.

Each of the conductive elements 410 may also include a tail, which in this example is at an opposite end of the conductive elements from the mating contact portions 462. Each tail may be configured for making a connection to another conductive structure within an interconnection system including connector 200. In this example, the tails are configured for connecting to conductive structures of a cable. In this example, tails 460 of signal conductors are configured differently than tails 466 of ground conductors. In the example of FIG. 4, tails 460 of the signal conductors of lead assembly 400 are in a plane, with at least an upper surface of the tail exposed through dielectric 430 such that a connection may be made to it.

Tails 466 of the ground conductors are also in a plane, which is parallel to, but offset from, the plane of the signal conductor tails 460. In this case, the tails 466 extend rearwards of the tails 460 of the signal conductors where tails 466 are joined through cable clamp plate 420.

Intermediate portions of the conductive elements (not numbered in FIG. 4) extend between and electrically connect the tail and the mating contact portions of each conductive element. The intermediate portions may be held within the dielectric 430.

The cable clamp plate is configured to secure a plurality of cables 416 to the terminal assembly. Some or all of the cables 416 may be configured as drainless twinax cables. The drainless twinax cable includes two cable conductors 418, each of which may be electrically and physically coupled to one or more of the conductive elements 410. Each of the cable conductors are surrounded by dielectric insulation 414 which electrically isolates the cable conductors from one another. A shield 412, which may be connected to ground, surrounds the cable conductors and dielectric insulation 414. The shield may be formed of a metal foil and may fully surround the circumference of the cable conductors. Surrounding the shield is an insulating jacket 424.

The conductors of the cables may be attached, such as by soldering or welding, to tails 460 of the conductive elements in the terminal assembly serving as signal conductors. The shields of the cables may be electrically connected to the ground structures of the terminal assembly via clamping. In the example of FIG. 4, cable clamp plate 420 is corrugated with peaks and valleys. Clamping force is provided by attaching the valleys of shield 440 to cable clamp plate 420 between cables, such that the cables are captured between peaks of shield 440 and cable clamp plate 420. The metal shield plate may be secured around the cables by welding (e.g., laser welding), overmolding, or another appropriate process, once an appropriate clamping force (e.g., 100 lbs.) is applied to the metal plate. In this example, cable clamp plate 420 includes multiple strain relief portions 426. The strain relief portions of FIG. 4 are I-shaped slots or openings formed in the cable clamp plate that allows the cable clamp plate to deform under clamping pressure securing the cables to the cable clamp plate. Such an arrangement may reduce or eliminate the likelihood of the cables being crushed or otherwise deformed by the clamping force.

As shown in FIG. 4, the terminal assembly 400 includes a ground strip 442 electrically interconnecting a subset of the conductive elements 410. The interconnected conductive elements, in this example are configured as ground conductors. The ground strip 442 may be laser welded or soldered to the selected ones of the conductive elements 410 near the end of the terminals, such as within 1.97 mm from an end of the conductive elements. In this example, ground strip 442 is welded to beams that form the mating contact portions 462 of the ground conductors.

A configuration as shown in FIG. 4 may provide suitable performance in a high speed connector. However, the inventors have recognized and appreciated techniques that may extend the frequency range over which a connector as shown in FIGS. 2-4 operates with suitable signal integrity. For example, the frequency at which insertion loss is greater than 0.5 dB and/or the frequency at which far end cross talk exceeds-40 dB may be extended to higher frequencies. As a result, the connector may carry data signals at higher data rates.

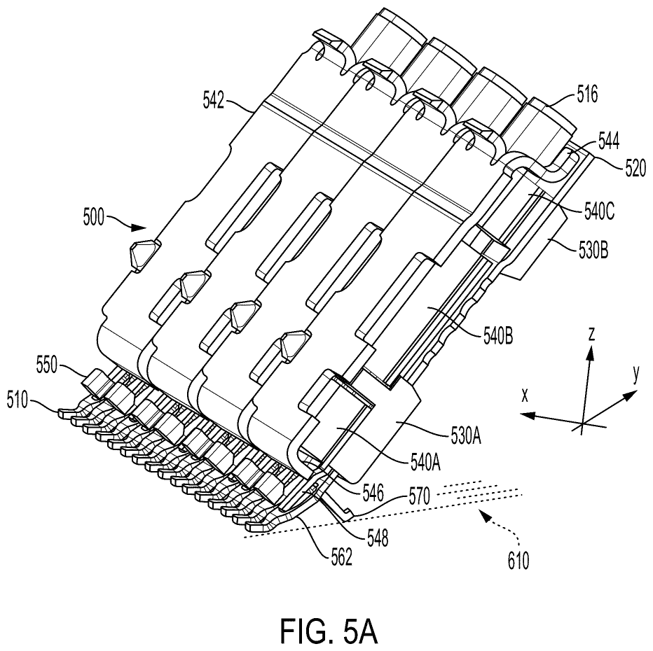

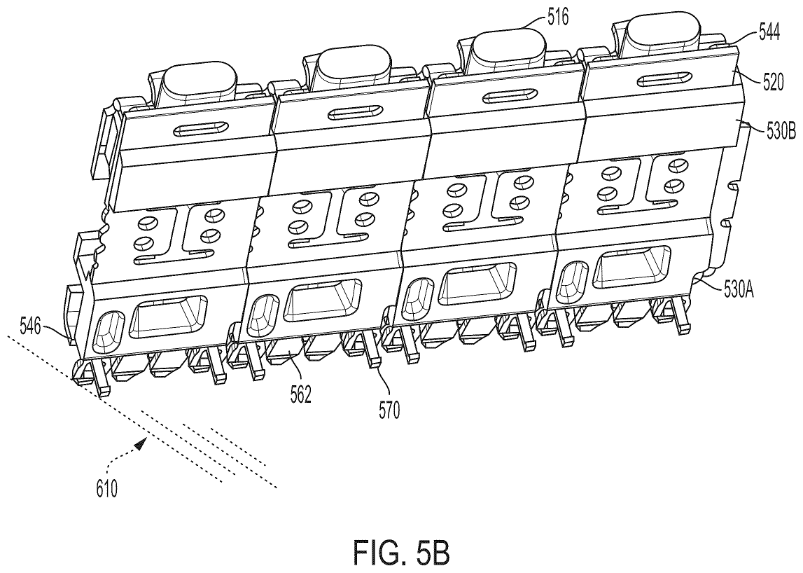

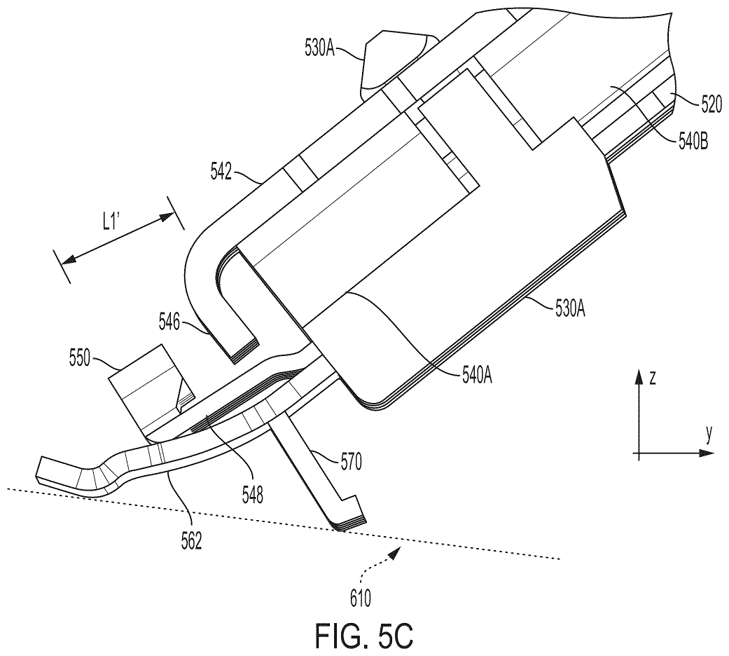

FIGS. 5A-5C illustrate a terminal assembly 500 made according to an alternative design. Terminal assembly 500 may be used in a connector 200 instead of or in addition to terminal assemblies 200 and may be manufactured using techniques and materials as described above in connection with terminal assembly 400, except for differences as described herein. Accordingly, one or more terminal assembles 500 may be stacked side-by-side to form a pressure mount connector.

As with terminal assembly 400, terminal assembly 500 includes multiple conductive elements 510 held in a column. In this example, the column includes conductive elements to terminate four cables 516. Each of the cables 516 is terminated to a group of conductive elements. In FIGS. 5A-5C, each of the cables 516 is a drainless twinax cable and is terminated to a group of conductive elements with two signal conductors, forming a differential pair, and two ground conductors, with one ground conductor on each side of the pair of signal conductors. In other examples each group may include more or fewer conductive elements. Each group, for example, may include two signals and one ground conductor, as shown in connection with FIG. 4, or one signal and two ground conductors.

A terminal assembly housing, here shown as dielectric 530A, may hold some or all of the conductive elements of the column. As with terminal assembly 400, the conductive elements may be stamped from a sheet of metal and overmolded with plastic or other dielectric to hold them together. After overmolding, the signal conductors may be severed from one another. As with terminal assembly 400, the ground conductors may be connected through a cable clamp plate 520.

Dielectric may be molded over multiple regions of the terminal assembly. In the example of FIGS. 5A-5C, a second dielectric region 530B is present. Dielectric region 530B is here shown as a separate region from dielectric 530A and may be molded at the same time or at a different time. In this case, dielectric region 530B may surround portions of the cables 516, and may resist forces applied to the cables, holding the cables to the terminal assembly.

FIGS. 5A-5C shows mating contact portions 562 of the conductive elements 510 extending out of dielectric 530A. The mating contact portions are configured as beams that will make contact to conductive structures on a substrate, such as printed circuit board 610, shown schematically in FIGS. 5A-5C.

One or more corrugated shield plates may be incorporated into terminal assembly 500. As described above in connection with shield plate 440, each of the corrugated shield plates may have peaks and valleys, with the peaks aligned with the conductors of the cables and the valleys against cable clamp plate. In FIGS. 5A-5C, three corrugated shield plates 540A, 540B and 540C are shown. The valleys of each may be welded to cable clamp plate 520. At least one of these corrugated shield plates may press a portion of the cables 516 with exposed shields against claim plate 520 such that the cable shield is connected to the ground conductors of the terminal assembly through the clamp plate 520. Others of the corrugated shield plates may clamp a portion of the cable with a jacket still intact against clamp plate 520. Yet others of the corrugated shield plates may cover portions of the cable in which the jacket, shield and optionally insulators of the cable conductors have been removed for termination. In such a configuration, the corrugated shield plate may provide shielding of the conductors of the cable instead of the cable shield. As a specific example, corrugated shield plate 540B may press portions of the cables with exposed shields against cable clamp plate 520. Corrugated shield plate 540C may press a jacketed portion of the cable against cable clamp plate 520. Corrugated shield plate 540A may provide shielding around exposed portions of the conductors of the cable.

Terminal assembly 500 also includes a ground strip 550, which, like ground strip 442, may electrically connect mating contact portions 562 of the conductive elements 510 configured as ground conductors. In this example, the ground strip 550 may not be welded or otherwise affixed to the mating contact portions. Rather, ground strip 550 may positioned such that, as the mating contact portions are pressed against a substrate, the mating contact portions 562 deflect to be close enough to ground strip 550 for electrical coupling over the higher frequency portion of the operating frequency range of the connector, such as above 20 GHz. Such coupling may be achieved through direct contact or may occur capacitively across a small gap.

In this example, a ground structure within the terminal assembly 500 may include ground extensions 548. Ground extensions 548 may extend from corrugated shield plate 540A, for example. Ground strip 550 may be formed at the end of the ground extensions 548. Such a configuration may be formed from a sheet of metal that is stamped and then formed into the desired shape.

FIG. 5C is a side view of a terminal assembly 500 in which a mating contact portion 562 of a ground conductor is visible. FIG. 5C shows the beam forming mating contact portion 562 in a deflected state, such as may result from the terminal assembly being pressed against a substrate. In this deflected state, mating contact portion 562 is pressed towards ground strip 550 and is sufficiently close to a valley portion of ground strip 550 that mating contact portion 562 is electrically coupled to ground strip 550. In the state illustrated in FIG. 5C, that coupling may be the result of contact between ground strip 550 that mating contact portion 562.

As the mating contact portions 562 of all of the conductive elements 510 may be similarly deflected upon pressing terminal assembly 500 against a substrate, the conductive elements aligned with the valleys of ground strip 550 may be similarly coupled to ground strip 550 such that they are connected through ground strip 550. In the example of FIGS. 5A-5C, the ground conductors of terminal assembly 500 are aligned with the valleys of ground strip 550 such that the grounds of the terminal assembly may be connected through ground strip 550 when a connector including terminal assembly 500 is pressed against a substrate to form a separable connection.

In this example, terminal assembly 500 additionally includes an outer shield plate 542. Outer shield plate may contact one or more of the corrugated shield plates 540A, 540B and/or 540C. These parts may be welded to one another or held together through other direct or indirect connections. Dielectric 530A may pass through openings in shield plate 542, attaching the shield plate to dielectric 530A. Such a configuration may result from molding protrusions in dielectric 530A and pressing shield plate 542 towards dielectric 530A with openings in shield plate 542 aligned with the protrusions such that the protrusions are forced through the openings, creating an interference fit. As another example of a construction technique, dielectric 530A might be molded with shield plate 532 held in place such that a portion of the molding material flows through openings in shield plate 532.

Outer shield plate 542 may include one or more portions that are attached to cable clamp plate 520, which may serve as a support member for the terminal assembly instead of or in addition to providing electrical connections between cable shields and ground conductors of the terminal assembly. In this example, shield plate 542 includes tabs 544 that bend towards cable clamp plate 520. Tabs 544 may be affixed to cable clamp plate 520, such as by welding, soldering, and or by insertion into a slot in clamp plate 520.

At an opposite edge of outer shield plate 542, shield plate 542 may be configured with a forward portion 546. The forward portion is bent relative to a body of shield plate 542. Whereas the body of shield plate 542 is generally parallel to which the conductive elements extend when in an undeflected state, forward portion 546 is approximately perpendicular to the conductive elements. Forward portion 546 may have one or more impacts on the performance of terminal assembly 500 when integrated into a pressure mount connector. Forward portion 546 may extend ground structures adjacent the signal conductors into the mating contact region, which may reduce impedance discontinuities. Forward portion 546 alternatively or additionally may attenuate radiation passing into or out of the regions of terminal assembly 500 in which conductors of the cable extend beyond the cable shield, which may reduce crosstalk. Alternatively or additionally, forward portion 546 may increase robustness of the connector by limiting deflection of mating contact portions 562 and/or ground extensions 548. Such a configuration otherwise might degrade the performance of the connector if these portions were overstress and yielded. If overstress, the contact force against a mating component might thereafter be inadequate to provide reliable connections.

The exemplary connector alternatively or additionally includes other features for improving signal integrity. FIGS. 5A-5C reveal that some or all of the conductive elements configured as ground conductors may include a secondary beam 570. The beam forming mating contact portion 562 of the ground conductors may serve as the primary beam. The secondary beam 570 may extend in a transverse direction with respect to the primary beam. In some examples, the primary beam may exert greater force against a complementary mating structure than the secondary beam. As seen for example in FIG. 5C, the primary beam extends in a forward direction and the secondary beam extends in a backwards direction such that the direction of the first beam makes an angle with respect to the direction of the secondary beam. That angle, for example, may be between 100 and 125 degrees in some examples.

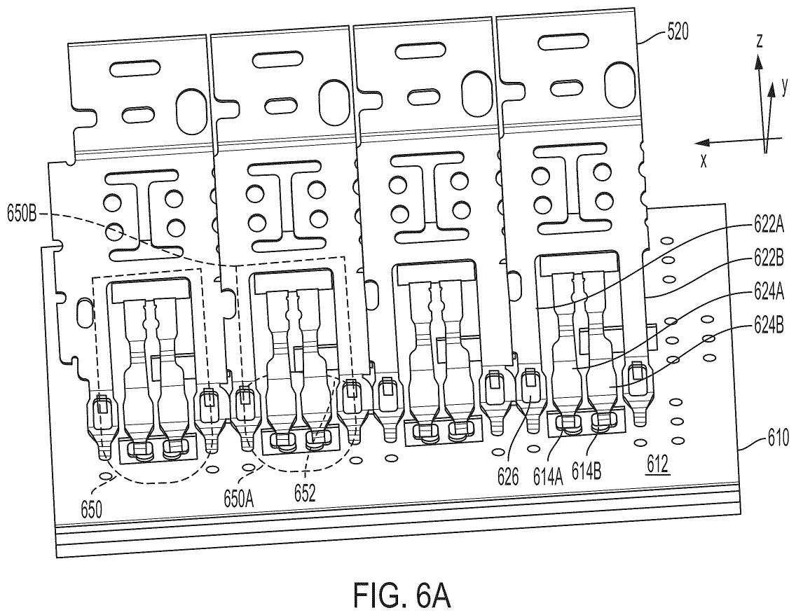

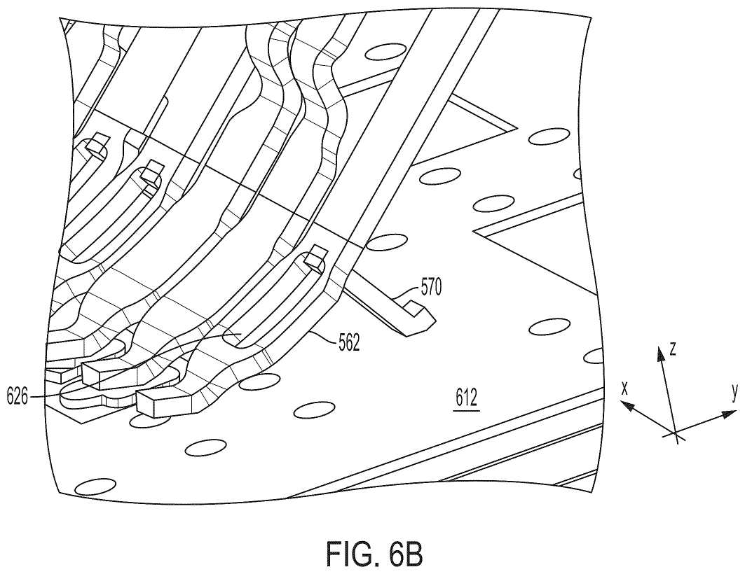

FIGS. 6A-6B illustrates terminal assembly 500 with certain components hidden to reveal the conductive elements of the terminal assembly and cable clamp plate 520. FIG. 6A shows the terminal assembly 500 pressed against a surface of a substrate, here illustrated as printed circuit board 610. This state may be created, for example, when a connector including terminal assembly 500 is pressed against printed circuit board 610 for mating. Components creating that pressing force are not shown but may be a frame as described above in connection with FIG. 2 or other mechanical components.

In the example illustrated, printed circuit board 610 has a ground pad over much of its surface, which may be referred to as a ground plane 612. The ground plane may be connected to other ground structures of printed circuit board 610 through shadow vias (not numbered), which are vias that make connections between conductors on different layers of the printed circuit board, but do not receive a tail of a component mounted to the printed circuit board. In the example illustrated, both the primary and secondary beams of the ground conductors press against ground plane 612.

FIG. 6A also shows rows of antipads (not numbered) formed in the ground plane, with pairs of signal pads 614A and 614B formed in the antipads. The antipads isolate the signal pads from the ground plane 612. Each signal pad may be connected to a trace or other conductive structure within printed circuit board 610 by one or more vias, the tops of which are visible but not numbered in FIG. 6A. Signal conductors 624A and 624B may press against respective signal pads 614A and 614B.

FIG. 6B is an enlarged view of one group of conductive elements, including in this example two signal conductors 624A and 624B and two ground conductors 622A and 622B. As shown in FIG. 6A, terminal assembly 500 includes multiple such groups in a column, with one group terminating a respective cable. In other examples, each group of conductive elements may have different numbers or types of conductive elements. In terminal assembly 400, for example, each group of conductive elements terminating a drainless twinax cable had two signal conductors and one ground conductor, producing a repeating pattern of ground (G)-signal(S)-signal(S), in contrast to the G-S-S-G pattern illustrate in FIG. 6A. Also, as illustrated by terminal assembly 400, groups of conductive elements configured to terminate different types of cables may be intermixed, such as groups to terminate single conductor cables and groups terminating twinax cables.

In the example of FIGS. 5A-6B, cable clamp plate 520 and outer shield plate 542 are depicted as having multiple segments, each segment corresponding the structures that terminate a single cable. Structures such as cable clamp plate 520 and outer shield plate 542 may be implemented as separate components that are held together, such as by a separate support component, such as a terminal assembly housing, which may be formed by dielectrics 530A and 530B. Alternatively or additionally, some or all of these structures may be integrally formed. For example, each of cable clamp plate 520 and outer shield plate 542 may be stamped from a sheet of in a size that spans multiple, up to all, of the segments for the terminal assembly.

In the example of FIGS. 6A-6B, each of the ground conductors 622A and 622B has a secondary beam 570. The secondary beam 570 may be formed separately from the primary beam and affixed to it, such as by welding. Alternatively, the secondary beam may be integrally formed with the primary beam, such as by cutting the secondary beam out of the primary beam. Holes 626, for example, in the primary beams indicate where material is cut from the primary beam and bent to form the secondary beam.

The inventors theorize that the secondary beams alter the ground structure of the terminal subassembly when pressed against a substrate in a way that reduces the impact of ground loops at high frequencies. Ground loops can introduce crosstalk and increase insertion loss for signals passing through the connector such that reducing the impact of ground loops improves signal integrity such that reducing the impact at high frequencies can extend the operating frequency range of the connector. Increasing the operating frequency range enables the connector to operate at higher data rates.

For example, FIG. 6A shows a ground loop 650 that may form in a conventional connector, without secondary beams 570 on the ground conductors and without ground strip 550. The ground loop incorporates the ground conductors, a portion of cable clamp plate 520 that connects those ground conductors and a portion of the ground structure of printed circuit board 610 through which those ground conductors are connected. Ground loop 650 has a length that is the sum of these path lengths.

FIG. 6A is annotated to show a conducting path 652 through those ground structures when the impact of secondary beams 570 is considered. Conducting path 652 passes through the secondary beams 570 and through the ground structure of printed circuit board 610. Conducting path 652 divides ground loop 650 into two smaller loops 650A and 650B. Each of these smaller loops impacts signal integrity at a higher frequency than ground loop 650. In this example, loop 650A closer to the tip of the conductive elements, is smaller than loop 650B.

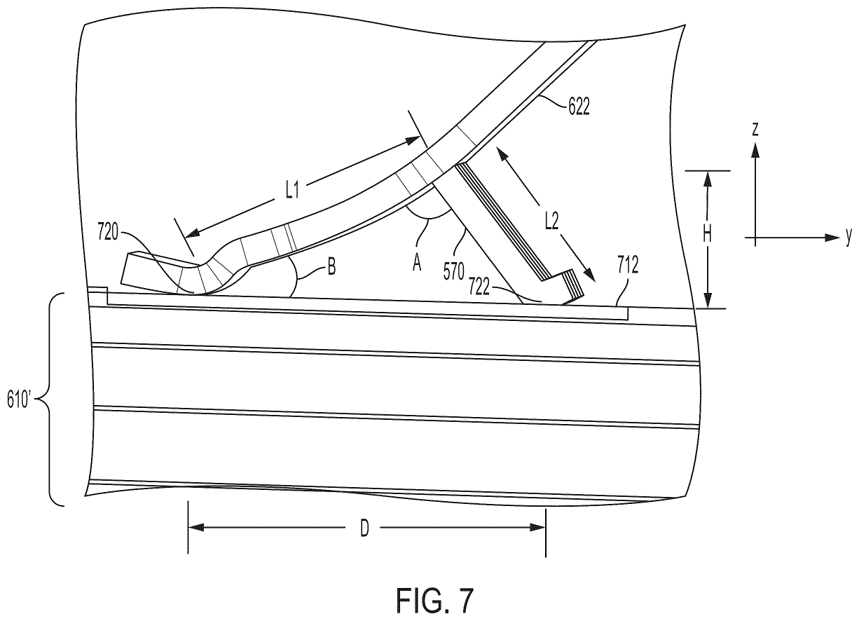

FIG. 7 is a side view of the tip of a ground conductor 622, which may be any of the ground conductors 622A or 622B. This figure shows the ground conductor in a deflected state, such as may result from pressing a connector including ground conductor 622 against a substrate for making a separable connection. The substrate may be a printed circuit board, such as printed circuit board 610. FIG. 7 illustrates that substrate as printed circuit board 610′, which has a construction similar to printed circuit board 610, including signal pads. In this example, rather than an expansive ground plane, the surface of printed circuit board 610′ includes separate ground pads 712 aligned with ground conductors.

Though less expansive than ground plane 612, ground pads 712 may nonetheless be longer than signal pads 614A and 614B. The ground pads, for example, may be 1.5 to 2 times the length of the signal pads. As specific examples of a high speed, high density connector, the ground pads may have a length in the range of 2 mm to 4 mm. The signal pads may be between 1 and 2 mm long. In connectors in which the signal and ground conductors are spaced on a uniform pitch, both signal and ground pads may have a width that is less than the pitch, such as 75% of the pitch, for example. As specific examples of pad width, the pads may be 0.25 mm to 0.35 mm wide.

In the example of FIG. 7, the ground pad 712 is long enough that both ground conductor 622, here acting as the primary beam, and second beam 570 contact pad 712. Ground conductor 622 has a contact surface 720 and second beam 570 has a contact surface 722. As can be seen, those beams extend in directions separated by an angle A. Angle A may be sufficiently large that the primary beam extends forward of the intersection of the primary and secondary beams, and the secondary beam extends backwards such that there is a separation D between the point at which the primary beam contacts pad 712 and the second beam 570 contacts pad 712.

When the beams are in a compressed state, as shown in FIG. 7, angle A may be between 100 and 150 degrees. When in an uncompressed state the, the angle A may be in a range between 100 and 125 degrees. The distance D in a compressed state may be between 0.5 mm and 1.5 mm, such as between 0.6 mm and 1.0 mm, with the separation distance between contact surfaces on the primary and secondary beams being about 15% smaller when not compressed, in some examples.

The inventors theorize that the impact of a ground loop encompassing conductive elements through a connector in which ground conductors are in a column with signal conductors depends on multiple factors, including separation between signal conductors and ground conductors, the frequency of signals passing through the connector, the length of the ground loop and the separation between ground conductors supporting the ground loop and other conductive structures, including conductive structures that form portions of the ground structure. For a high speed, high density connector a ground loop may be highly impactful where ground conductors supporting the ground loop are separated by a small distance from other conductors over a substantial distance. Accordingly, reducing the size of the ground loop through ground conductors that are closely spaced to other ground conductors may be most impactful on performance of the connector.

In a pressure mount connector, such as is illustrated in FIG. 7, such a condition may exist near the tip of the ground conductors 622 where those ground conductors are pressed against ground structures on the surface of a substrate. In the example of FIG. 7, at the tip, the primary beam makes an acute angle B with respect to the surface of the pad 712. The acute angle B, for example, may be in the range of 20 to 40 degrees, or 25 to 35 degrees in some examples, with smaller angles within these ranges when in the compressed state than in the uncompressed state.

With this configuration, the primary beam is separated from pad 712 a small distance over a substantial length. As can be seen in FIG. 7, the separation between ground conductor 622 and pad 712 starts at essentially 0 at contact surface 720 and increases to a height H above the surface of the pad a distance L1 from the contact surface to the base of the second beam. The height H may be 0.2 to 0.6 mm, in some examples. The length L1, for example, may be between 0.6 mm and 1.0 mm. The second beam 570 may have a length L2, which may be between 0.4 mm and 0.8 mm in some examples.

These structures, including the portion of the primary beam represented by the dimension L1, and the secondary beam support a ground loop 650A. The inventors theorize that this ground loop is close enough to pad 712 over a sufficiently long distance that shortening the ground loop impacts performance of the connector. As described above in connection with FIG. 6A, inclusion of the second beams 570 shortens the ground loop through these structures, from ground loop 650 to ground loop 650A. As a result, performance may be improved.

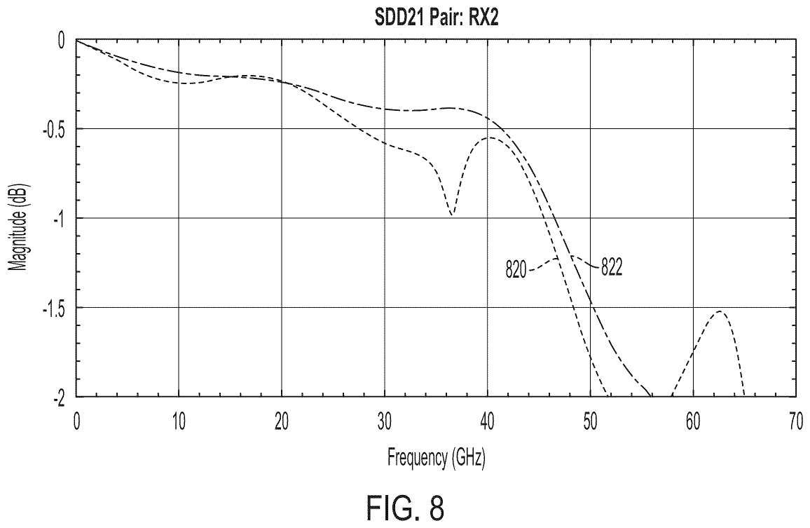

FIG. 8 is a plot showing a simulation of insertion loss for a signal conductor in a connector. The plot shows the effect of adding a secondary beam to a primary beam of the ground conductors. Performance is simulated in a state without a ground strip 550. Curve 820 shows insertion loss as a function of frequency without the secondary beam. Curve 822 shows insertion loss as a function of frequency with the secondary beam. A comparison of the plots shows that the inclusion of the secondary beam provides for a more uniform and lower insertion loss at frequencies up to about 40 GHz, but the design without the secondary beam had an insertion loss above-0.5 dB at a frequency of about 28 GHz with a significant increase in insertion loss around 36 GHZ.

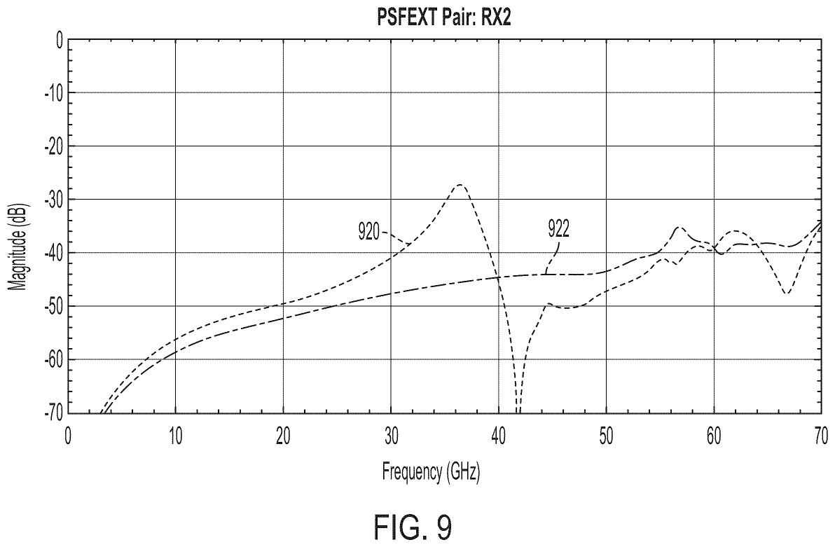

FIG. 9 is a plot showing a simulation of far end cross talk for a signal conductor in a connector. The plot shows the effect of adding a secondary beam to a primary beam of the ground conductors. Performance is simulated in a state without a ground strip 550. Curve 920 shows far end cross talk as a function of frequency without the secondary beam. Curve 922 shows far end cross talk as a function of frequency with the secondary beam. A comparison of the plots shows that the inclusion of the secondary beam provides for a more uniform and lower far end cross talk at frequencies up to about 40 GHz, but the design without the secondary beam had a spike in far end cross talk over a frequency about 30 to 40 GHz.

Inclusion of the secondary beams therefore may increase the operating frequency range of the connector from below 30 GHz to above 40 GHz. Signals in this frequency range may support data rates per channel on the order of 120-160 Gbps.

The addition of ground extension 548 and ground strip 550 may also reduce the length of the ground loop formed through ground conductors that are closely to the ground structures of the substrate. As can be seen, for example in FIG. 5C, ground strip 550 can connect grounds in a column of conductive elements at a location between the contact surface of the primary beam and the intersection of the primary and secondary beams. Such a connector has the effect of splitting ground loop 650A (FIG. 6A) into two smaller loops, which is theorized to increase the frequency at which the ground loops significantly impact performance of the connector. Further, the length of which the longer of these two smaller loops encompasses the portion of the primary beam indicated as spanning the length L1′ in FIG. 5C. As a result, ground extension 548 and ground strip 550 may increase the performance of a high speed, high density connector.

Ground extension 548 and ground strip 550, which provide a structure that connects together ground conductors at their ends, may be used with secondary beams 570 or may be used in structures without secondary beams 570, as improved performance may result in both cases.

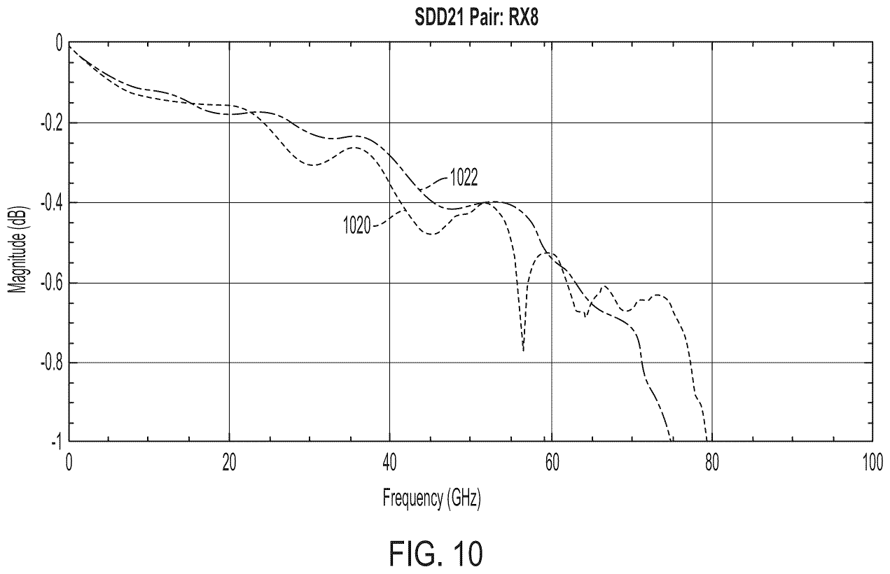

FIG. 10 is a plot showing a simulation of insertion loss for a signal conductor in a connector. The plot shows the effect of adding ground extension 548 and ground strip 550. Performance is simulated in a state without secondary beams added to the primary beams of the ground conductors. Curve 1020 shows insertion loss as a function of frequency without ground extension 548 and ground strip 550. Curve 1022 shows insertion loss as a function of frequency with ground extension 548 and ground strip 550. A comparison of the plots shows that the inclusion of ground extension 548 and ground strip 550 provides for a more uniform and lower insertion loss particularly at higher frequencies.

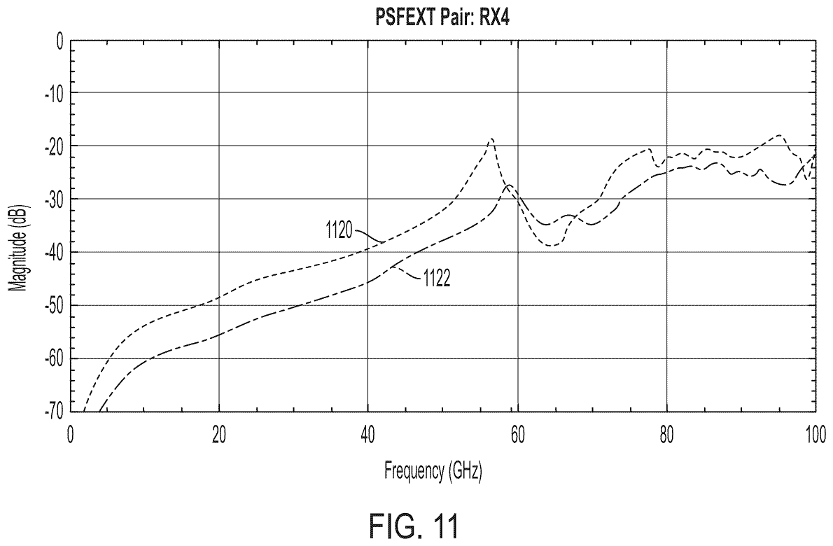

FIG. 11 is a plot showing a simulation of far end cross talk for a signal conductor in a connector. The plot shows the effect of adding a ground extension 548 and ground strip 550. Performance is simulated in a state without a secondary beam 570. Curve 1120 shows far end cross talk as a function of frequency without ground extension 548 and ground strip 550. Curve 1122 shows far end cross talk as a function of frequency with ground extension 548 and ground strip 550. A comparison of the plots shows that the inclusion of ground extension 548 and ground strip 550 provides for a more uniform and lower crosstalk, particularly at higher frequencies.

In the foregoing examples, the conductive structures simulated in FIGS. 8 and 9 differed from those simulated in FIGS. 10 and 11, such as by the average separation between the ground conductors and conductive structures of a printed circuit board to which those ground conductors mate. Accordingly, the plots of insertion loss or crosstalk, without structures such as secondary beam 570 and without ground strip 550, are not identical across FIGS. 8-11. Nonetheless, these simulations are useful in indicating relative improvement by adding such structures individually. Such structures may be used together in the same connector for even greater relative performance improvement.

Having thus described several embodiments, it is to be appreciated various alterations, modifications, and improvements may readily occur to those skilled in the art. Such alterations, modifications, and improvements are intended to be within the spirit and scope of the invention.

Various changes may be made to the illustrative structures shown and described herein. As a specific example of a possible variation, the use of a secondary beam was described in connection with a pressure mount connector. Such a secondary beam may alternatively or additionally be used in a connector in which contact force is generated by insertion of a mating component into a connector. For example, in many I/O connectors, mating contact force is generated by deflection of the beam portions of conductive elements of the connector upon insertion of a paddle card into the connector. In that scenario, the paddle card may play the role the substrate, such as printed circuit board 610 or 610′ described above.

As another example, while a drainless twinax cable is shown in FIG. 4, other cable configurations may be employed, including those having more or less than 2 cable conductors (e.g., 1 cable conductor), one or more drain wires, and/or shields in other configurations. For example, as shown in FIG. 5, the cable clamp plate also accommodates single conductor cables 450, which each include single conductors 452 surrounded by a single layer of dielectric insulation 454.

As another example, mechanical force to press a connector against a substrate was described as being generated by a frame attached to the substrate. In other examples, that force may be generated by other structures, such as clips or a hinged lid attached to the substrate. Further, the mechanical components generating force may not be attached to the substrate. The force may be generated, for example, by a structure that is mechanically coupled to an electronic enclosure for the electronic device. For example, closing a lid of the enclosure may generate force on connectors inside the enclosure.

As yet another example, FIG. 2 illustrates terminal assemblies held together as each is inserted into a housing. In other examples, the terminal assemblies may be held by other support structures, such as metal strips along one or more edges of the terminal assemblies.

Further, FIG. 2 illustrates a connector with four lead assemblies. Connectors may be formed with more or fewer lead assemblies. In some examples, a connector may have two lead assemblies.

As a further example, a cable clamp plate was described as forming a portion of a clamp to hold cables to a terminal subassembly and to act as a ground member, connecting multiple ground conductors together. A connector may contain one or more ground members connecting multiple ground conductors, whether or not the ground member(s) also perform a clamping function.

As an example of another variation, the connector may be configured for a frequency range of interest, which may depend on the operating parameters of the system in which such a connector is used, but may generally have an upper limit between about 15 GHz and 224 GHz, such as 25 GHz, 30 GHz, 40 GHZ, 56 GHZ, 112 GHz, or 224 GHz, although higher frequencies or lower frequencies may be of interest in some applications. Some connector designs may have frequency ranges of interest that span only a portion of this range, such as 1 to 10 GHz or 5 to 35 GHz or 56 to 112 GHZ.

The operating frequency range for an interconnection system may be determined based on the range of frequencies that can pass through the interconnection with acceptable signal integrity. Signal integrity may be measured in terms of a number of criteria that depend on the application for which an interconnection system is designed. Some of these criteria may relate to the propagation of the signal along a single-ended signal path, a differential signal path, a hollow waveguide, or any other type of signal path. Two examples of such criteria are the attenuation of a signal along a signal path or the reflection of a signal from a signal path.

Other criteria may relate to interaction of multiple distinct signal paths. Such criteria may include, for example, near end cross talk, defined as the portion of a signal injected on one signal path at one end of the interconnection system that is measurable at any other signal path on the same end of the interconnection system. Another such criterion may be far end cross talk, defined as the portion of a signal injected on one signal path at one end of the interconnection system that is measurable at any other signal path on the other end of the interconnection system.

As specific examples, it could be required that signal path attenuation be no more than 3 dB power loss, reflected power ratio be no greater than-20 dB, and individual signal path to signal path crosstalk contributions be no greater than-50 dB. Because these characteristics are frequency dependent, the operating range of an interconnection system is defined as the range of frequencies over which the specified criteria are met.

Designs of an electrical connector are described herein that improve signal integrity for high frequency signals, such as at frequencies in the GHz range, including up to about 25 GHz or up to about 40 GHz, up to about 56 GHz or up to about 60 GHz or up to about 75 GHz or up to about 112 GHz or higher, while maintaining high density, such as with a spacing between adjacent mating contacts on the order of 3 mm or less, including center-to-center spacing between adjacent contacts in a column of between 1 mm and 2.5 mm or between 2 mm and 2.5 mm, for example. Spacing between columns of mating contact portions may be similar, although there is no requirement that the spacing between all mating contacts in a connector be the same.

Manufacturing techniques may also be varied. For example, embodiments are described in which a connector 200 is formed by organizing a plurality of terminal subassemblies. An equivalent structure may be formed in other ways, such as by inserting a plurality of shield pieces and conductive elements into a molded housing.

Connector manufacturing techniques were described using specific connector configurations as examples. The techniques described herein for reducing the impact of ground loops near the tips of ground conductors are applicable to connectors in other configurations, such as backplane connectors, cable connectors, stacking connectors, mezzanine connectors, I/O connectors, chip sockets, etc.

For example, conductive elements in a connector were illustrated with tails configured for termination to conductors of cables. To configure a connector for other uses, the tails of the conductive elements may be in other configurations. Some or all of the tails may be configured for connection to a printed circuit board. Some or all of the tails may be press fit “eye of the needle” compliant sections that are designed to fit within vias of printed circuit boards, or may be surface mount elements, solderable pins, etc., as aspects of the present disclosure are not limited to the use of any particular mechanism for attaching connectors to printed circuit boards.

The present disclosure is not limited to the details of construction or the arrangements of components set forth in the foregoing description and/or the drawings. Various embodiments are provided solely for purposes of illustration, and the concepts described herein are capable of being practiced or carried out in other ways. Also, the phraseology and terminology used herein are for the purpose of description and should not be regarded as limiting. The use of “including,” “comprising,” “having,” “containing,” or “involving,” and variations thereof herein, is meant to encompass the items listed thereafter (or equivalents thereof) and/or as additional items.

Accordingly, the foregoing description and drawings are by way of example only.

What is claimed is:

1. A connector configured to mate with a complementary mating structure having a first surface, comprising:
a housing;
a plurality of signal conductive elements held by the housing; and
a plurality of ground conductive elements held by the housing, each ground conductive element comprising:
a first beam forming a first mating contact portion, the first beam extending in a first direction; and
a second beam forming a second mating contact portion, the second beam extending in a second direction, wherein the second direction is transverse to the first direction such that the first and second contact portions are both adapted to contact a conductive pad formed on the first surface when the connector mates with the complementary mating structure.

2. The connector of claim 1, wherein the first direction is opposite the second direction when projected on a plane defined by the first surface.

3. The connector of claim 1, wherein the first beam, the second beam and the conductive pad are in a ground loop when the connector mates with the complementary mating structure.

4. The connector of claim 3, wherein the first beam and the second beam are configured such that a conducting path through the first beam, the second beam and the conductive pad between the first beam and the second beam is between 2 mm and 3 mm when the connector mates with the complementary mating structure.

5. The connector of claim 1, wherein the first and second contact portions are spaced apart from each other, when the connector is mated with the complementary mating structure, by a distance that is between 0.8 mm and 1.4 mm.

6. The connector of claim 1, further comprising a ground member from which first and second ground conductive elements of the plurality of ground conductive elements extend, wherein first and second signal conductive elements of the plurality of signal conductive elements are disposed between the first ground conductive element and the second conductive element.

7. The connector of claim 1, wherein the second beam has a length between 0.4 mm and 0.8 mm.

8. The connector of claim 1, wherein:
the first mating contact portion has a first contact surface;
a base of the second beam is joined to the first beam; and
a distance between the first contact surface and the base of the second beam is between 0.6 mm and 1.0 mm.

9. The connector of claim 1, wherein:
the first beam and the second beam extend in directions separated by an angle between 100 and 125 degrees, when the first beam and the second beams are in an uncompressed state.

10. The connector of claim 1, wherein:
the connector is configured such that, when the connector is mated to the complementary mating structure, the second beam is joined to the first beam at a point that is 0.2 to 0.6 mm from the first surface.

11. The connector of claim 1, wherein the plurality of ground conductive elements are configured so that pressing the connector towards the first surface of the complementary connector, as the connector is mating with the complementary connector, causes the first and second contact portions to slide away from each other on the conductive pad.

12. The connector of claim 1, further comprising a ground strip positioned such that pressing the connector towards the first surface of the complementary mating structure, when the connector is mated with the complementary mating structure, causes at least one ground conductive element to electrically couple to the ground strip.

13. The connector of claim 12, wherein:
pressing the connector towards the plane of the first surface of the complementary connector, when the connector is mated with the complementary connector, causes at least two of the plurality of ground conductive elements to electrically coupled to the ground strip.

14. The connector of claim 13, wherein:
the connector further comprises a ground shield welded to the at least two of the plurality of ground conductive elements;
the ground shield has a plurality of extensions extending therefrom; and
the ground strip is attached to the plurality of extensions.

15. The connector of claim 1, further comprising a plurality of cables, each cable being connected to a respective pair of the plurality of signal conductive elements.

16. The connector of claim 1, wherein the connector exhibits, at a frequency of 35 GHZ, a far end crosstalk that is between −40 dB and −50 dB.

17. The connector of claim 1, wherein the plurality of signal conductive elements and the plurality of ground conductive elements are arranged in a plurality of columns.

18. The connector of claim 1, wherein:
the first beam is adapted to exert a first force normal to a plane defined by the first surface of the complementary mating structure when the connector is mated with the complementary mating structure, and
the second beam is adapted to exert a second force normal to the plane defined by the first surface of the complementary connector when the connector is mated with the complementary mating structure, the first force being greater than the second force.

19. The connector of claim 18, wherein each signal conductive element comprises a third beam forming a third mating contact portion, wherein the first contact portions and the third contact portions form a column.

20. The connector of claim 1, wherein the first beam further comprises an enclosed opening, and the second beam joins a region of the ground conductive element that is adjacent the enclosed opening.

21. A connector configured to mate with a complementary mating structure having a first surface, comprising:
a housing;
a plurality of signal conductive elements held by the housing; and
a plurality of ground conductive elements held by the housing, each ground conductive element comprising a first beam comprising a first mating contact surface and a second beam forming a second mating contact surface, wherein the first and second contact portions are both configured to contact a conductive pad on the first surface when the connector mates with the complementary mating structure,
wherein the plurality of ground conductive elements are configured so that pressing the connector towards the first surface, when the connector is mated with the complementary mating structure, causes the first and second contact portions to slide away from each other on the conductive pad.

22. The connector of claim 21, wherein the first beam, the second beam and the conductive pad are in a ground loop when the connector mates with the complementary mating structure.

23. The connector of claim 22, wherein the first beam and the second beam are configured such that a conducting path through the first beam, the second beam and the conductive pad between the first beam and the second beam is between 2 mm and 3 mm when the connector mates with the complementary mating structure.

24. The connector of claim 23, wherein the first and second contact portions are spaced apart from each other, when the connector is mated with the complementary mating structure, by a distance that is between 0.8 mm and 1.4 mm.

25. The connector of claim 21, wherein the first and second contact portions are spaced apart from each other, when the connector is mated with the complementary mating structure, by a distance that is between 0.8 mm and 1.4 mm.

26. A method for mating a connector with a complementary mating structure having a first surface, the connector comprising a plurality of signal conductive elements and a plurality of ground conductive elements, each ground conductive element comprising first and second beams, the method comprising:
placing the plurality of signal conductive elements in contact with a first plurality of conductive pads formed on the first surface of the complementary connector; and
placing the plurality of ground conductive elements in contact with one or more conductive pads on the first surface of the complementary mating structure at least in part by:
placing the first beams in contact with pads of the one or more conductive pads;
placing the second beams in contact with pads of the one or more conductive pads; and
causing the first beams and the second beams to slide away from each other on the pads of the one or more conductive pads.

27. The method of claim 26, wherein placing the plurality of ground conductive elements in contact with pads of the one or more conductive pads further comprises forming a plurality of ground loops, each ground loop traversing at least portions of two first beams, two second beams and a ground structure within the complementary mating structure.

28. The method of claim 26, wherein placing the plurality of ground conductive elements in contact with the one or more conductive pads further comprises:
exerting a first force normal to the first surface of the complementary mating structure with the first beam; and
exerting a second force normal to the first surface of the complementary mating structure with the second beam, wherein the first force is greater than the second force.

29. The method of claim 28, wherein the first beams and the plurality of signal conductive elements form a column.
